(19) United States
(12) Patent Application Publication
(10) Pub. No.: US 2004/0145034 A1
(43) Pub. Date: Jul. 29, 2004

(54) Semiconductor device

(76) Inventors: Toru Fujioka, Kokubunji (JP); Toshihiko Shimizu, Tokorozawa (JP); Isao Yoshida, Hinode (JP); Mamoru Ito, Tamamura (JP); Koji Odaira, Takasaki (JP); Tetsuya Iida, Musashimurayama (JP)

Correspondence Address: Mattingly, Stanger & Malur, P.C., 1800 Diagonal Road, Suite 370, Alexandria, VA, 22314, US

(21) Appl. No.: 10/753,525

(22) Filed: Jan. 9, 2004

(30) Foreign Application Priority Data
Jan. 23, 2003 (JP) 2003-015055

(51) Int. Cl. H01L 29/40

(52) U.S. Cl. 257/664

(57) ABSTRACT

A semiconductor device for amplification with enhanced performance is provided for use at a base station. The semiconductor device has a semiconductor chip for amplification and a transmission line substrate in the package of an amplifier used at a base station for mobile communication equipment such as a mobile phone. Stubs formed in the empty region of the transmission line substrate are connected to an output of the semiconductor chip for amplification by using bonding wires. The stubs and the bonding wires have been designed to form a resonant circuit resonating at a frequency double the fundamental frequency of an output signal from the semiconductor chip for amplification. This suppresses a doubled-frequency-wave signal of the signal outputted from the semiconductor chip for amplification and achieves an improvement in the transmission efficiency of the amplifier and a reduction in transmission distortion.

### BACKGROUND OF THE INVENTION

The present invention relates to semiconductor device technologies and, more particularly, to a technology which is effective when applied to a high-output power amplifier for use at a base station.

A high-output power amplifier used at a base station for mobile communication equipment such as a mobile phone aims at transmitting and receiving large-capacity information including not only data on speech, characters, and a still picture but also data on a motion picture and the like. For this purpose, it is necessary to process a large amount of data at a high speed so that the improvement of the performance of the high-output power amplifier has been pursued. There is a high-output power amplifier which has an internal matching circuit within a package to derive the performance of a active element provided therein. For the internal matching circuit, a matching method using a low-low transmission line has been used widely. In short, a transmission line interposed between the output of the amplifier element in the package and the output terminal of the package has been imparted with not only the function as the transmission line but also the function as the matching circuit.

An exemplary structure is disclosed in Japanese Unexamined Patent Publication No. Hei 8(1996)-130424, which is a high-efficiency power amplifier circuit. In an attempt to improve the efficiency by controlling second and third harmonic waves without lowering an impedance in the vicinity of the transistor element thereof, each of a series resonant circuit for the second harmonic wave and a series resonant circuit for the third harmonic wave is connected to an output of the transistor element via a matching line having a length of λ/4 where λ is the wavelength of a fundamental wave (see, e.g., Patent Document 1).

Another exemplary structure is disclosed in, e.g., Japanese Unexamined Patent Publication No. Hei 11(1999)-145744, which is a microwave amplifier having a capacitor for processing a doubled-frequency wave and a capacitor for matching a fundamental wave. In an attempt to remove constraints on matching conditions resulting from a conflict in placing the capacitor for processing a doubled-frequency wave and the capacitor for matching a fundamental wave, the comb-teeth-shaped capacitor for matching a fundamental wave is disposed on a dielectric substrate to be located between the output terminal of a semiconductor element and an output retrieval line with a comb-teeth-shaped portion facing the semiconductor element and the capacitor for processing a doubled-frequency wave is disposed in a gap between the comb teeth (see, e.g., Patent Document 2).

Still another exemplary structure is disclosed in Japanese Unexamined Patent Publication No. 2001-111364, in which, to obtain a microwave output signal having a high-output characteristic and a reduced distortion component, a bonding wire functioning as an inductance is interposed between an amplifier element and a package output terminal to have one end connected to the drain of the amplifier element and the other end connected in series with a capacitor such that the bonding wire and the capacitor constitute such a series resonant circuit as to eliminate a differential frequency between a plurality of carrier frequencies (see, e.g., Patent Document 3).

Yet another exemplary structure is disclosed in Japanese Unexamined Patent Publication No. Hei 5 (1993)-226951, which is the internal matching circuit of an RF transistor. In the internal matching circuit, if an open stub (microstrip line) having a ¼ wavelength of a wave at a frequency double the frequency in use is connected to the output terminal of the transistor, the physical length of the open stub and the mounting area of the microstrip line may be increased disadvantageously. To prevent this, an open stub slightly shorter than the ¼ wavelength of the doubled-frequency wave is formed on a high dielectric constant substrate forming a capacitor portion connected to the drain of the transistor (see, e.g., Patent Document 4).

Still another exemplary structure is disclosed in Japanese Unexamined Patent Publication No. Hei 9(1997)-260975, in which, to eliminate intricacy involved in the changing of the configuration of an open stub and the resultant changing of a substrate and a resonator, which is necessary when a frequency band in use is to be changed, a plurality of distinct open stubs are disposed on a substrate formed with an RF strip line having a protruding configuration and connected to an output of a transistor such that the open stubs are located on both sides of the RF strip line and bonding wires provide connections between the strip line and the open stubs and also between the plurality of open stubs, whereby a desired center frequency is obtained (see, e.g., Patent Document 5).

Yet another exemplary structure is disclosed in Japanese Unexamined Patent Publication No. Hei 7(1995)-263979, which is a doubled-frequency-wave or tripled-frequency-wave series resonant circuit connected in parallel with an output load to the output side of a transistor via a transmission line (see, e.g., Patent Document 6).

[Patent Document 1]

Japanese Unexamined Patent Publication No. Hei 8(1996)-130424

[Patent Document 2]

Japanese Unexamined Patent Publication No. Hei 11(1999)-145744

[Patent Document 3]

Japanese Unexamined Patent Publication No. 2001-111364

[Patent Document 4]

Japanese Unexamined Patent Publication No. Hei 5(1993)-226951

[Patent Document 5] Japanese Unexamined Patent Publication No. Hei 9(1997)-260975

[Patent Document 6] Japanese Unexamined Patent Publication No. Hei 7(1995)-263979

### SUMMARY OF THE INVENTION

However, the realization of a high-output power amplifier small in size and high in performance (having a high signal transmission efficiency and a reduced distortion) presents a significant challenge.

It is therefore an object of the present invention to provide a technology which enables an improvement in the performance of a semiconductor device for amplification which is used primarily at a base station.

The above and other objects and novel features of the present invention will become apparent from the description of the present specification and the accompanying drawings.

A brief description will be given to the outline of the representative aspects of the present invention disclosed in the present application.

Specifically, the present invention has a structure in which a semiconductor active element and a transmission line substrate are provided in a package composing a semiconductor device for amplification which is used at a base station and stubs formed on the empty region of the transmission line substrate are connected to an output of the semiconductor active element by using conductor lines to provide a resonant circuit which resonates at a frequency double the fundamental frequency of an output signal from the semiconductor active element.

### BRIEF DESCRIPTION OF THE DRAWINGS

FIG. 1 is a view illustrating the package of an amplifier for use at a base station, which has been examined by the present inventorss;

FIG. 2 is a principal-portion enlarged plan view of the region CA of FIG. 1;

FIG. 3 is an equivalent circuit diagram of the region CA of FIG. 1;

FIG. 4 is a view illustrating an example of a base station apparatus using a semiconductor device according to an embodiment of the present invention;

FIG. 5 is a view illustrating the package of a semiconductor device composing the base station amplifying unit of the base station apparatus of FIG. 1;

FIG. 6 is a cross-sectional view taken along the line Y1-Y1 of FIG. 5;

FIG. 7 is a principal-portion cross-sectional view of an amplifier element in the semiconductor device of FIG. 5;

FIG. 8 is a principal-portion enlarged plan view of the semiconductor device of FIG. 5;

FIG. 9 is a perspective view of the transmission line substrate shown in FIGS. 5 and 8;

FIG. 10 is an equivalent circuit diagram of the amplification path in FIGS. 5 and 8;

FIG. 11 is a graph conceptually showing the respective transmission characteristics of output internal matching circuits according to the embodiment of the present invention and the example examined by the present inventors and shown in FIG. 1 and the like, each relative to frequencies;

FIG. 12 is a graph showing a result of simulating the frequency characteristic of a frequency-doubled-wave resonant circuit using stubs and wires;

FIG. 13 is a graph showing, for comparison, the results of simulating the input-output characteristic of an amplifier for use at a base station to which the present embodiment has been applied and that of an amplifier according to the example examined by the present inventors and described with reference to FIGS. 1 to 3;

FIG. 14 is a graph showing, for comparison, the results of simulating the input-efficiency characteristic of the semiconductor device described in the embodiment of the present invention and that of the semiconductor device according to the example examined by the present inventors and described with reference to FIGS. 1 to 3;

FIG. 15 is a graph showing, for comparison, the results of simulating the respective distortion characteristics of the semiconductor device described in the embodiment of the present invention and that of the semiconductor device according to the example examined by the present inventors and described with reference to FIGS. 1 to 3;

FIG. 16 is a partial plan view of another semiconductor device examined by the present inventors;

FIG. 17 is a circuit diagram equivalent to FIG. 16;

FIG. 18 is a principal-portion plan view of a semiconductor device according to another embodiment of the present invention;

FIG. 19 is a circuit diagram equivalent to FIG. 18;

FIG. 20 is a principal-portion plan view showing a variation of the connection of bonding wires in the semiconductor device of FIG. 18;

FIG. 21 is a principal-portion plan view showing another variation of the connection of bonding wires in the semiconductor device of FIG. 18;

FIG. 22 is a graph showing the respective results of examining output powers (Pout (dBm)) for the different types shown in FIGS. 20 and 21;

FIG. 23 is a graph showing the respective results of examining power added efficiencies (PAE (%)) for the different types shown in FIGS. 20 and 21;

FIG. 24 is a graph showing the respective results of examining third-order intermodulation distortions for the different types shown in FIGS. 20 and 21; and

FIG. 25 is a principal-portion plan view of a semiconductor device according to still another embodiment of the present invention.

### DESCRIPTION OF THE PREFERRED EMBODIMENTS

A description will be given herein below to the present invention by dividing it, if necessary, into a plurality of sections or embodiments for the sake of convenience. However, they are by no means irrelevant to each other unless shown particularly explicitly and are mutually related to each other such that one of the sections or embodiments is a variation or a detailed or complementary description of some or all of the others. If the number and the like of elements (including the number, numerical value, amount, and range thereof) are referred to in the following embodiments, they are not limited to specific numbers unless shown particularly explicitly or unless they are obviously limited to specific numbers in principle. The number and the like of the elements may be not less than and not more than specific numbers. It will easily be appreciated that, in the following embodiments, the components thereof (including also elements and steps) are not necessarily indispensable unless shown particularly explicitly or unless the components are considered to be obviously indispensable. Likewise, if the configurations, positional relationship, and the like of the components are referred to in the following embodiments, the configurations and the like are assumed to include those substantially proximate or similar thereto unless shown particularly explicitly or unless obviously they are not in principle. The same shall apply to the foregoing numeric values and the range. Throughout the drawings for illustrating the embodiments of the present invention, parts having the same functions are designated by the same reference numerals and the repeated description thereof will be omitted. There are cases where even plan views may be hatched for easy viewing of the drawings used in the embodiments of the present invention. The embodiments of the present invention will be described in detail with reference to the drawings.

Embodiment 1

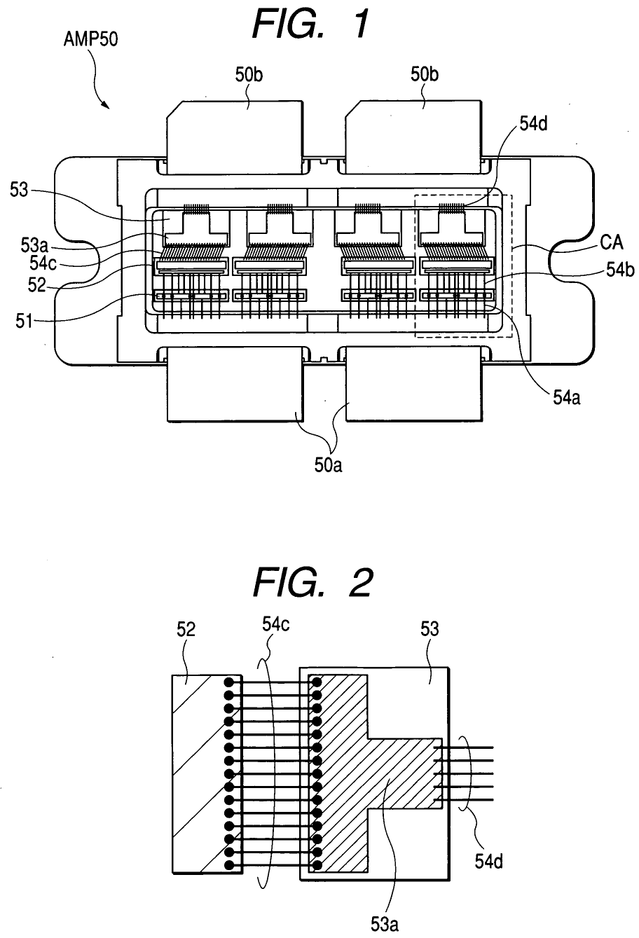

FIG. 1 is a view illustrating the package of an amplifier AMP50 for use at a base station, which has been examined by the present inventors. FIG. 2 is a principal-portion enlarged plan view of the region CA of FIG. 1. The package of the amplifier AMP50 has two input leads 50a protruding from one of the longer edges of the package and two output leads 50b protruding from the other of the longer edges of the package. In the input leads 50a and output leads 50b forming the pairs, respective paths for amplifying the same signal in two systems are disposed in parallel. In short, the total of four amplification paths are contained in the package. In the respective amplification paths, MOS (Metal Oxide Semiconductor) capacitors 51, MOSFETs (Metal Oxide Semiconductor Field Effect Transistors) 52, and transmission line substrates 53 are disposed in directions from the input leads 50a to the output leads 50b. The input leads 50a are connected electrically to the MOS capacitors 51 via bonding wires 54a. The MOS capacitors 51 are connected electrically to the respective gate electrodes of the MOSFETs 52 via bonding wires 54b. The respective drain electrodes of the MOSFETs 52 are connected electrically to the transmission lines 53a of the transmission line substrates 53 via bonding wires 54c. The transmission lines 53a are further connected electrically to the output leads 50b via bonding wires 54d. Each of the foregoing MOSFETs 52 has the function as an amplifier element. As the MOSFET 52, an LD (Laterally Diffused) MOSFET, e.g., which has a total gate width as large as, e.g., 12.9 cm is used to enable a high output (several hundreds of volts). To retrieve an output with a low loss from the low-impedance MOSFET 52 (i.e., to derive the performance of the device), an internal matching circuit is connected to the input/output of the MOSFET 52. The internal matching circuit is composed of the MOS capacitor 51, the transmission line 53a, and the bonding wires 54a to 54d which are contained in the package. The bonding wires 54a to 54d function as an internal matching circuit element equivalently to a coil. Each of the transmission lines 53a has a protruding plan configuration having a width larger at a portion thereof closer to the MOSFET 52 than at a portion thereof closer to the outer lead 50b. In such a package, a region for mounting a new circuit element is barely left.

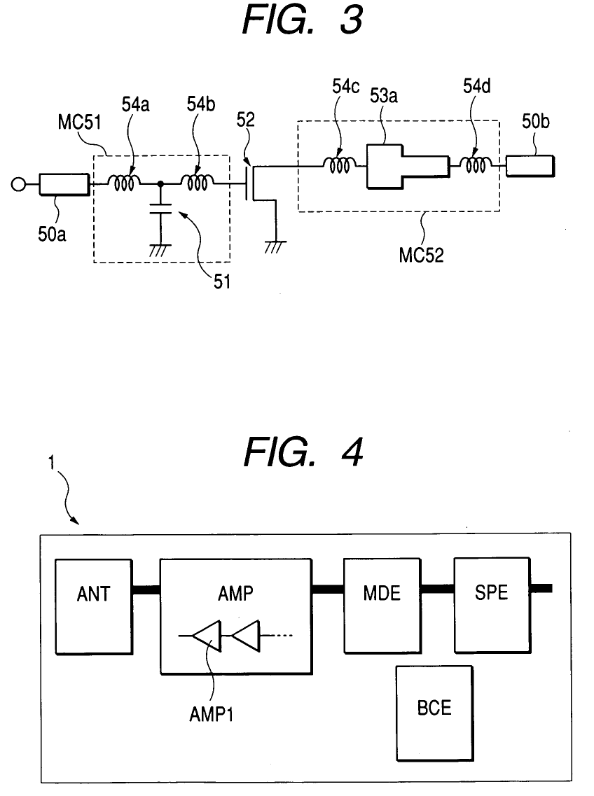

FIG. 3 shows a circuit equivalent to the region CA of FIG. 1, in which a reference numeral MC51 denotes an input internal matching circuit and a reference numeral MC52 denotes an output internal matching circuit. The performance of the MOSFET 52 has been derived by the input internal matching circuit MC51 and the output internal matching circuit MC52. In particular, the transmission line 53a of the output internal matching circuit MC52, which is low in loss, allows a high output and a high gain. As the low-loss transmission line substrate 53, a ceramic substrate having a dielectric constant of, e.g., 38 is used. Examples of such a MOSFET device of internal-matching-circuit type are disclosed in M. Morikawa et al. “High Efficient 2.2-GHz Si Power MOSFETs for Cellular Base Station Applications”, Proc of 1999 RAWCON, p.405, August 1999 and in K. Inoue et al., “A High Efficiency High Power GaAs Push-Pull FET for W-CDMA Base Stations”, Proc. of 2001 International Symposium on Power Semiconductor Devices & ICs, Osaka.

In an amplifier as mentioned above, however, harmonic waves have not been controlled so that it is difficult to perform high-efficiency and low-distortion signal transmission. In particular, an output impedance tends to lower as the gate width of an amplifier element, the saturation current thereof, and the like have increased in recent years to respond to a high output request so that it has become difficult to perform impedance conversion and successfully derive the characteristics of the amplifier element.

To eliminate the difficulty, the present embodiment performs harmonic wave control and thereby provides an amplifier capable of high-efficiency and low-distortion signal transmission. By properly using the empty region of the transmission substrate for the harmonic wave control, a high-performance amplifier is implemented without incurring an increase in the size of the package.

The semiconductor device according to the present embodiment will be described by using specific examples.

FIG. 4 is a view illustrating an example of a base station apparatus 1 using the semiconductor device according to the present embodiment. The base station apparatus 1 is a base station apparatus for use in, e.g., the 2.14 GHz band W-CDMA (Wideband Code Division Multiple Access), which constitutes a digital mobile communication system for processing a radio signal by using mobile communication equipment such as a mobile phone. The base station apparatus 1 has a speech processing unit SPE, a base station modulating/demodulating unit MDE, a base station amplifying unit AMP, a base station antenna ANT, and a base station control unit BCE. The speech processing unit SPE has the function of converting a speech signal to a row of digital codes. The base station modulating/demodulating unit MDE has the function of converting a base band signal to a harmonic wave signal. The base station amplifying unit AMP has the function of amplifying a transmitted/received signal to a desired level. The base station antenna ANT has the function of transmitting, as a radio signal, the signal amplified by the base station amplifying unit AMP. The base station control unit BCE has the function of allocating radio channels and performing channel switching with an adjacent base station. The semiconductor device according to the present embodiment is used as a high-output power amplifier AMP1 (hereinafter simply referred to as an amplifier AMP1) composing the foregoing base station amplifying unit AMP.

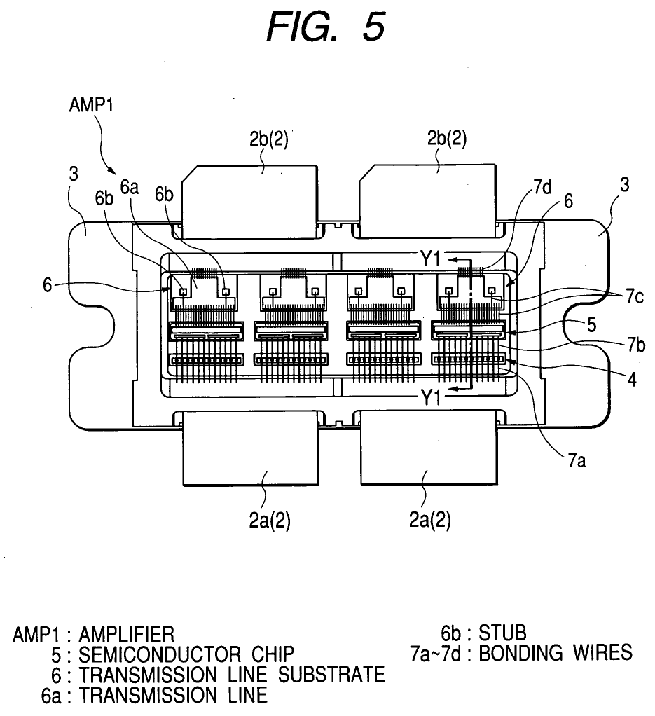

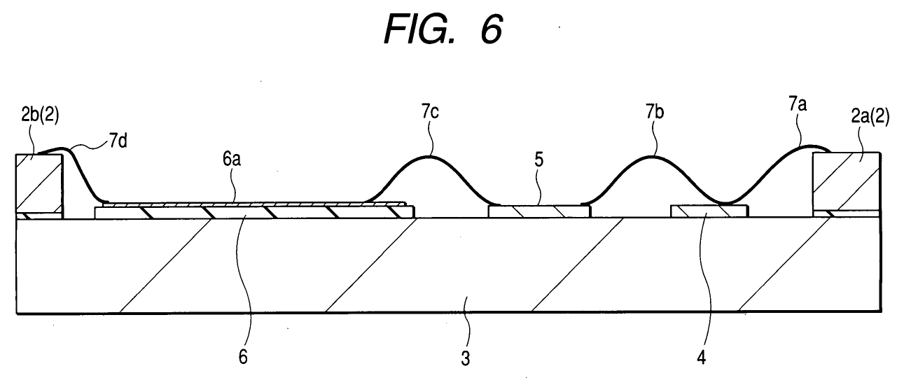

FIG. 5 is a view illustrating the package of the amplifier AMP1 according to the present embodiment. FIG. 6 is a cross-sectional view taken along the line Y1-Y1 of FIG. 5. The fundamental frequency of a signal is, e.g., 2.14 GHz. As an output of the amplifier AMP1, a high output on the order of, e.g., 250 W can be obtained. In the package of the amplifier AMP1, an internal matching circuit for performing impedance matching with an external circuit is embedded together with an amplifier element having a large total gate width not to impair an RF characteristic, which will be described later. The package of the amplifier AMP1 has a flat package structure having two leads 2 protruding from each of the longer edges of the package and stems 3 protruding individually from the shorter edges of the package on a one-by-one basis. The two leads 2a protruding from one of the longer edges of the package of the amplifier AMP1 are gate leads for inputting, while the two leads 2b protruding from the other of the longer edges of the package are drain leads for outputting. Each of the gate leads 2b for outputting is partly notched to be recognized as it is. The stems 3 are made of, e.g., a metal high in heat dissipation and have the function of dissipating heat generated during the operation of the amplifier AMP1 to the outside as well as the function of enabling mechanical mounting of the amplifier AMP1 on the base station apparatus 1. Each of the stems 3 is composed of a single plate-like part which has both ends in a lengthwise direction protruding from the both shorter edges of the amplifier AMP1. The leads 2 (2a and 2b) and the stems 3 are insulated from each other.

In the gate leads 2a for inputting and gate leads 2b for outputting forming the pairs, respective paths for amplifying the same signal in two systems are disposed in parallel. In short, the total of four amplification paths are contained compactly in the package of the amplifier AMP1. In the respective amplification paths, semiconductor chips 4 for capacitor elements (hereinafter simply referred to as capacitor chips), semiconductor chips 5 for amplifier elements (semiconductor active elements) (hereinafter simply referred to as amplifier chips), and transmission line substrates 6 are disposed in proximity in directions from the gate leads 2a for inputting to the gate leads 2b for outputting. The gate leads 2a for inputting are connected electrically to the capacitor chips 4 via bonding wires (hereinafter simply referred to as wires) 7a. The capacitor chips 4 are connected electrically to the respective gate electrodes of the amplifier chips 5 via wires 7b. The respective drain electrodes of the amplifier chips 5 are connected electrically to transmission lines 6a and stubs (conductor pieces) 6b on the transmission line substrates 6. The transmission lines 6a are further connected electrically to the gate leads 2b for outputting via wires 7d. The operation of the amplifier AMP1 has adopted a push-pull operation mode, which allows the use of a wider band by suppressing an impedance conversion ratio and has the effect of canceling out an even-ordered nonlinear component. A description will be given to the operation of the amplifier AMP1. An RF signal inputted to the gate leads 2a for inputting is transmitted to the capacitor chip 4 via the wire 7a, inputted from the capacitance chip 4 to the input portion (gate pad) of the amplifier chip 5 via the wire 7b to be amplified by the amplifier chip 5, transmitted from the output portion (drain pad) of the amplifier chip 5 to the transmission line substrate 6 via the wire 7c, and transmitted via the transmission line substrate 6 to the lead 2b for outputting via the wire 7d to be outputted.

The capacitor chip 4 has, e.g., a plurality of MOS (Metal Oxide Semiconductor) capacitors and the total capacitance thereof is on the order of, e.g., 150 pF. The amplifier chip 5 has a plurality of power MOSFETs of, e.g., LDMOSFET (Laterally Diffused Metal Oxide Semiconductor Field Effect Transistor; hereinafter simply referred to as LDMOS) type and has high linearity and high-output and high-efficiency performance. The breakdown voltage of the amplifier chip 5 is, e.g., about 80 V and the threshold value Vₜₕ thereof is, e.g., about 2.5 V. The total gate width (the sum of the respective lengths of the plurality of power MOSFETs in directions substantially orthogonal to the directions of drain currents) of the amplifier chips 5 has been adjusted to be as large as, e.g., about 13.0 cm to provide a high output (several hundreds of volts). However, the total gate width is not limited to 13.0 cm and it may be, e.g., 20 mm or more. Preferably, the total gate width is 10 cm or more or 11 cm or more. The output impedance of the amplifier chip 5 is as low as, e.g., about 0.3 Ω. However, the output impedance of the amplifier chip 5 is not limited to 0.3 Ω and it may be, e.g., 2 Ω or less. Preferably, the output impedance of the amplifier chip 5 is 1 Ω or less. The gate voltage of the amplifier chip 5 under operation is, e.g., about 2.9V. The power source (drain) voltage of the amplifier chip 5 under operation is as high as, e.g., about 28 V, which allows a high output. The planar dimensions of the amplifier chip 5 are, e.g., about 5 mm in a lengthwise direction and, e.g., about 1.5 mm in a widthwise direction. An example of the structure of the LDMOS will be described later in detail. To be small in size and low in loss, the transmission line substrate 6 has a ceramic substrate (dielectric) having a specific dielectric constant of, e.g., about 38 as a base substrate. According to the result of the examination made by the present inventors, the specific dielectric constant of the ceramic substrate of the transmission line substrate 6 is preferably higher than 20. The transmission lines 6a and the stubs 6b are formed on the same principal surface of the transmission line substrates 6, while a conductor film is formed over substantially the entire back surface of the transmission line substrate 6. The conductor film on the back surface of the transmission line substrate 6 is connected electrically to the stems 3 and set to a reference potential (ground potential) of, e.g., zero (0) V. The lengthwise planar dimension of the transmission line substrate 6 is, e.g., about 4.8 mm, the widthwise planar dimension thereof is, e.g., about 3.6 mm, and the cross-sectional thickness thereof is, e.g., about 0.127 mm. The transmission line 6a and the stubs 6b will be described later in detail.

The capacitance chip 4, the transmission line substrate 6, and the wires 7a to 7d have the function as the internal matching circuit. The matching of a fundamental wave has been subjected to impedance conversion such that the efficiency, distortion, and output are optimally balanced. The provision of such an internal matching circuit enables the low-loss retrieval of an output from the low-impedance amplifier chip 5, i.e., the derivation of the performance of the device. Each of the wires 7a to 7d is made of aluminum and has a diameter of, e.g., about 50 μm. The wires 7a to 7d function as an internal matching circuit element equivalently to a coil element. The inductances of the wires 7a to 7d have been adjusted by adjusting the number of the wires 7a to 7d, the connecting points thereof, the lengths thereof, the loop heights thereof, and the like. To improve the frequency characteristics of the circuit such as output, efficiency, gain, and distortion within the band, the inductance of each of the wires 7a to 7d is normally designed to provide the frequency characteristics in a wider band. Of the wires 7a to 7d, the wire 7c having a lower impedance and used to provide a connection between the amplifier chip 5 and the transmission line 6a is highly sensitive to the RF characteristic (such as power, efficiency, gain, or distortion). Since a large current flows in the drain, a voltage drop due to the resistance component of the wire 7c should be prevented. Accordingly, the inductance value of the wire 7c is preferably lower so that the present embodiment has set the number of the wires 7c provided for each of the amplification paths to, e.g., about 24.

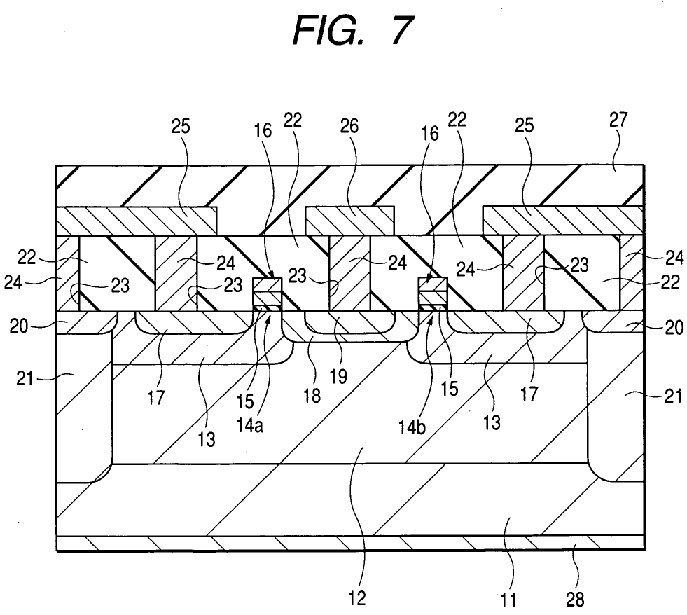

A description will be given to an example of the amplifier chip 5. FIG. 7 is a principal-portion cross-sectional view of the amplifier chip 5. A p⁻-type semiconductor layer (epitaxial silicon layer) 12 is formed by epitaxial growth or the like on a semiconductor substrate (hereinafter referred to as the substrate) 11 made of p⁺-type monocrystalline silicon (Si) having a specific resistance of, e.g., about 1 to 10 Ω cm. Each of p-type well regions 13 has been formed in the semiconductor layer 12 through ion implantation of an impurity such as, e.g., boron (B). In the principal surface of the substrate 11 (i.e., the principal surface of the semiconductor layer 12), n-channel LDMOSs 14a and 14b have been formed. Each of gate insulating films 15 for the LDMOSs 14a and 14b is composed of, e.g., a thin silicon oxide film or the like that has been formed by, e.g., thermal oxidation. The respective gate electrodes (input electrodes) 16 of the LDMOSs 14a and 14b have been formed by patterning, e.g., a polycrystalline silicon film and a metal silicide layer (e.g., a titanium silicide layer or cobalt silicide layer) formed on the principal surface of the substrate 11 by photolithography and etching. Each of n⁺-type semiconductor regions (n⁺-type diffusion layers) 17 as the respective source regions of the LDMOSs 14a and 14b has been formed in the p-type well region 13. The LDMOSs 14a and 14b have a common drain region formed between the respective gate electrodes 16 thereof to have an LDD (Lightly Doped Drain) structure including an n⁻-type semiconductor region (n⁻-type diffusion layer) 18 and an n⁺-type semiconductor region (n⁺-type diffusion layer) 19 higher in impurity concentration than the n⁻-type semiconductor region 18. Each of the n⁺-type semiconductor region 17, the n⁻-type semiconductor region 18, and the n⁺-type semiconductor region 19 has been formed through ion implantation of an impurity such as phosphorus (P). In the p-type well regions 13, p⁺-type semiconductor regions (p⁺-type impurity diffusion layers) 20 have been formed through ion implantation of an impurity such as boron (B). A p⁺⁺-type semiconductor region (p⁺⁺-type punch-through region or p⁺⁺-type impurity diffusion layer) 21 is formed in a region underlying each of the p⁺-type semiconductor regions 20, i.e., between the p⁺-type semiconductor region 20 and the substrate 11 through ion implantation of an impurity such as boron (B). An insulating film 22 composed of, e.g., a silicon oxide film is formed on the principal surface of the substrate 11 in such a manner as to cover the gate electrodes 16. Contact holes 23 each for exposing the n⁺-type semiconductor region 17, the n⁺-type semiconductor region 19 or the p⁺-type semiconductor region 20 are formed in the insulating film 22. Plugs 24 each composed of, e.g., a barrier film and a tungsten film are buried in the respective contact holes 23. Source electrodes (source wiring electrodes or ground electrodes) 25 connected electrically to the n⁺-type semiconductor regions 17 and to the p⁺-type semiconductor regions 20 via the plugs 24 and a drain electrode (drain wiring electrode or output electrode) 26 connected electrically to the n⁺-type semiconductor region 19 via the plug 24 are formed on the insulating film 22. The source electrodes 25 and the drain electrode 26 can be formed by patterning, e.g., an aluminum alloy film or the like formed on the insulating film 22 by photolithography and etching. The source electrodes 25 and the drain electrode 26 can also be formed of a multilayer film consisting of a barrier film and an aluminum alloy film. An insulating film 27 is formed on the insulating film 22 in such a manner as to cover the source electrodes 25 and the drain electrode 26. Although other wiring layers, interlayer insulating films, and the like may be formed on the insulating film 27 if necessary, the depiction and description thereof is omitted herein for the sake of clarity. A conductor layer (back surface electrode) 28 composed of, e.g., a metal layer is formed on the back surface (the surface opposite to the principal surface) of the substrate 11. Consequently, the source electrodes 25 are connected electrically to the conductor layer 28 via the plugs 24, the p⁺-type semiconductor regions 20, the p⁺⁺-type semiconductor regions 21, and the semiconductor substrate 11. The portion shown in FIG. 7 is the minimum unit of a repetitive pattern and the structure of FIG. 7 is repeatedly formed as required to compose a single amplifier element as an entirety. In other words, a plurality of unit amplifier elements (unit semiconductor elements), which are unit MOSFETs (the LDMOSs 14a or the LDMOSs 14b), are connected in parallel to compose a single amplifier element.

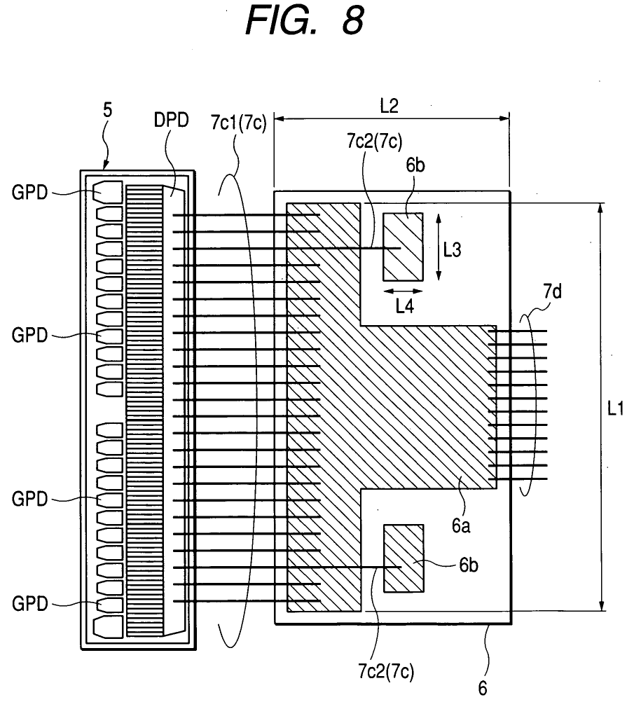

FIG. 8 is a principal-portion enlarged plan view showing the amplifier chip 5 and the transmission line substrate 6 in one amplification path, which have been extracted from FIG. 5.

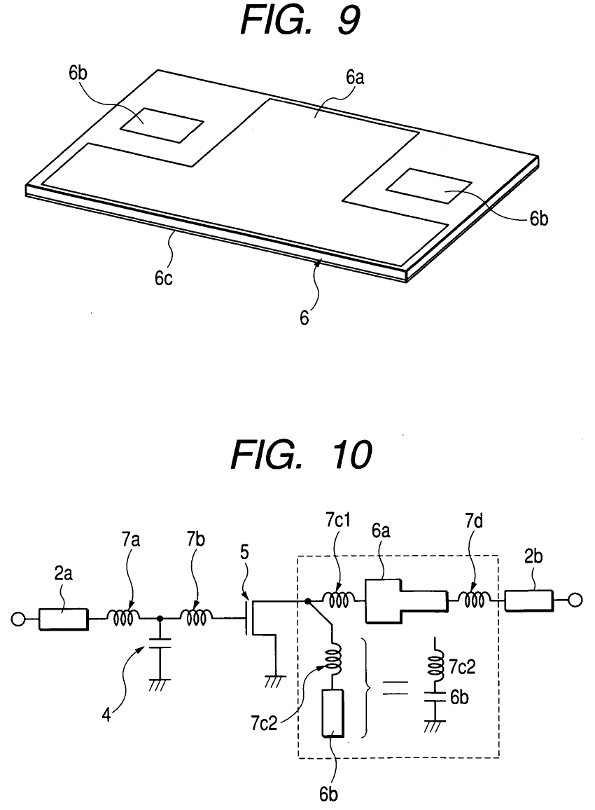

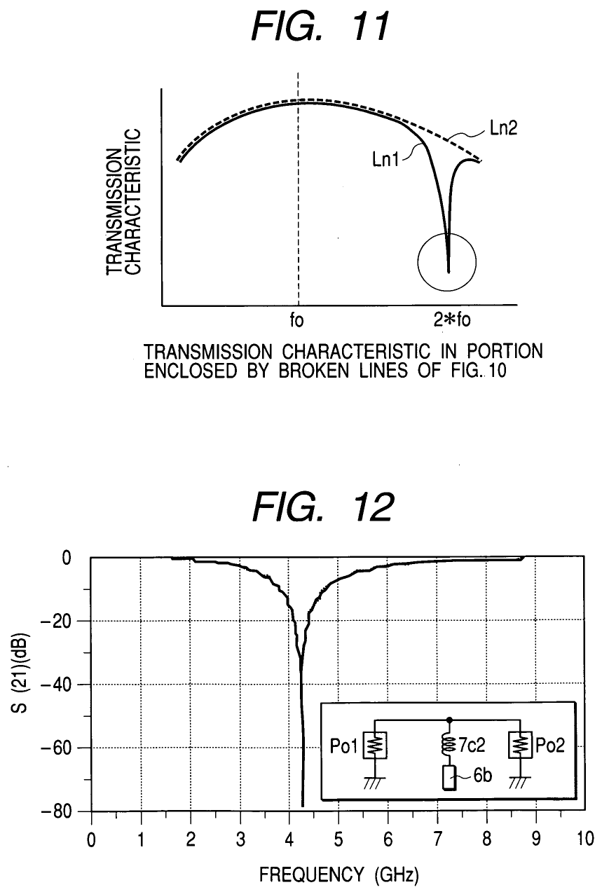

FIG. 9 is a perspective view of the transmission line substrate 6. FIG. 10 shows a circuit equivalent to one amplification path in the amplifier AMP1 according to the present embodiment.

The amplifier chip 5 has a rectangular plan configuration which is longer in the vertical direction of FIG. 8 and shorter in the lateral direction of FIG. 8. A plurality of gate pads (input portions) GPD and a single drain pad (output portion) DPD are disposed on the principal surface of the amplifier chip 5. The gate pads GPD are the input terminals of the amplifier chip 5 which are arranged in juxtaposition along one of the longer edges of the amplifier chip 5. The wires 7b (see FIGS. 5 and 6) mentioned above are bonded directly to the gate pads GPD through which the capacitor chip 4 and the gate leads 2a for inputting are connected electrically to each other. The drain pad DPD is the output terminal of the amplifier chip 5 which is formed to extend from one end of the amplifier chip 5 to the other end thereof along the other longer edge thereof. The plurality of wires 7c are bonded directly to the drain pad DPD. The drain pad DPD is connected electrically to the transmission line 6a on the transmission line substrate 6 via the plurality of wires (first conductor lines) 7c1 (7c) arranged in parallel. The drain pad DPD is also connected electrically to the stubs 6b on the transmission line substrate 6 via the wires (second conductor lines) 7c2 (7c). By thus forming the drain pad DPD into a plan configuration extending along the longer edge of the amplifier chip 5, the flexibility of the positions at which the wires 7c (7c1 and 7c2) are bonded to the drain pad DPD can be increased so that the connecting portions of the wires 7c (7c1 and 7c2) and the spacings between the adjacent ones thereof are easily adjustable. The back-surface (the surface of the amplifier chip 5 opposite to the principal surface thereof) source of the amplifier chip 5 is connected electrically to the stems 3.

The transmission line 6a and the stubs 6b are disposed on the principal surface of the transmission line substrate 6, while the conductor film 6c (see FIG. 9) is formed over the entire back surface (the surface of the transmission line substrate 6 opposite to the principal surface thereof) of the transmission line substrate 6. The conductor film 6c is connected electrically to the stems 3 and set to a reference potential (ground potential) of, e.g., zero (0) V. The transmission line 6a is composed of a metal film made of, e.g., gold (Au) or the like and has the function as the internal matching circuit, as described above. By disposing the transmission line 6a having the function as the internal matching circuit in immediate proximity to the amplifier chip 5 and providing a direct connection between the drain pad DPD of the amplifier chip 5 and the transmission line 6a by using the plurality of wires 7c1, a loss in transmitted signal can be reduced. The transmission line 6a has been formed into, e.g., a protruding (or T-shaped) plan configuration. Specifically, the transmission line 6a is a combination of transmission lines having different widths and has a configuration which is wider at a portion thereof closer to the amplifier chip 5 and narrower at a portion thereof closer to the lead 2b. The transmission line 6a has been formed into a protruding plan configuration for the matching of a fundamental wave in a wider band. That is, the impedance of the gate leads 2b for outputting of the amplifier AMP1 should be adjusted to a high value of, e.g., about 5 Ω in contrast to the impedance of the output of the amplifier chip 5 which is as low as, e.g., 0.3 Ω. To provide a matching circuit with a sufficiently wide frequency band, it is necessary to increase the width of the portion of the transmission line 6a closer to the amplifier chip 5 such that it has a low characteristic impedance and reduce the width of the transmission line 6a from midway in a direction away from the amplifier chip 5 such that the characteristic impedance is increased. In other words, the amplifier AMP1 according to the present embodiment is constructed to be advantageous in impedance conversion in the amplifier chip 5 with a low impedance. However, the plan configuration of the transmission line 6a is not limited thereto and can be changed variously provided that it attains the foregoing object. For example, the transmission line 6a may also be formed into a tapered pattern having a width which gradually decreases with distance from the amplifier chip 5 toward the gate lead 2b for outputting. The lengthwise planar dimension L1 of the transmission line 6a is, e.g., about 4.7 mm and the widthwise planar direction L2 thereof is, e.g., about 3.4 mm. The transmission line 6a is disposed such that the wider portion thereof is along the drain pad DPD of the amplifier chip 5. This is because a loss is smaller as the width of the portion of the transmission line 6a closer to the amplifier chip 5 is larger. The wire 7c1 bonded to the drain pad DPD of the amplifier chip 5 is bonded to the wider portion of the transmission line 6a. The plurality of wires 7d are connected to the narrower portion of the transmission line 6a. The impedance of the fundamental wave of a transmitted signal is converted by the transmission line 6a and the wires 7c1 and 7d connected thereto to an impedance which renders RF characteristics such as a transmission efficiency, power, and a distortion excellent.

In the present embodiment, the two stubs (open stubs) 6b are disposed on the principal surface of the transmission line substrate 6. Each of the stubs 6b is composed of, e.g., a metal film made of gold or the like which is the same as composing, e.g., the transmission line 6a and functions equivalently to a capacitor grounded relative to an RF signal (see FIG. 10). Specifically, a capacitor is provided which functions by using the stubs 6b on the principal surface of the transmission line substrate 6 and the conductor film 6c on the back surface of the transmission line substrate 6 as capacitor electrodes and using the transmission line substrate 6 (ceramic substrate) between the stubs 6b and the conductor film 6c as a capacitor insulating film. The wires 7c2 bonded to the drain pad DPD of the amplifier chip 5 are bonded to the stubs 6b. The wires 7c2 function equivalently to a coil relative to an RF signal. It follows therefore that a coil composed of the wires 7c2 and a capacitor composed of the stubs 6b are connected in series between the output of the amplifier chip 5 and the ground potential (see FIG. 10). The stubs 6b and the wires 7c2 have been designed to control (suppress or remove) the harmonic waves, particularly the doubled-frequency wave (second harmonic wave). In other words, each of the wires 7c2 and the stubs 6b has been designed such that the inductance value of the wire 7c2 and the capacitance value of the stub 6b resonate in series with the frequency of the doubled-frequency wave (since the wavelength of the fundamental wave is 2.14 GHz, that of the doubled-frequency wave is 4.28 GHz) but are open to the fundamental wave. Specifically, the size of the stub 6b, the length (loop) of the wire 7c2, and the like are adjusted such that a series resonant circuit having the stub 6b and the wire 7c2 is short-circuited with the doubled-frequency wave. Since the wire 7c2 and the stub 6b thus resonate at the frequency of the doubled-frequency wave, it is possible to bring the impedance of the drain pad DPD of the amplifier chip 5 with the doubled-frequency wave into a substantially short-circuited state. The reason for the occurrence of a loss in a transistor is that a voltage is applied while a current is flowing. If the waveform of the voltage is shaped into a configuration closer to a rectangle to reduce the loss, the efficiency can be enhanced. An efficiency of 100% is theoretically possible with an amplifier on the class F. To shape the voltage waveform into a rectangular configuration, it is sufficient to short-circuit the even-ordered harmonic waves and open the odd-ordered harmonic waves. However, since it is difficult to control each of the harmonic waves, the doubled-frequency wave is short-circuited in the present embodiment, which is substantially effective (control of a higher-ordered harmonic wave is less effective). This improves the efficiency of the amplifier AMP1 and reduces the power consumption of the amplifier AMP1. Since the LDMOS of the amplifier chip 5 operates non-linearly, a large signal is outputted. Accordingly, a higher-ordered harmonic wave (distortion component) is inevitably outputted into the output of the amplifier 5. In particular, the doubled-frequency wave (second harmonic wave) outputted from the amplifier chip 5 is reflected by the foregoing output internal matching circuit, injected again into the amplifier chip 5, mixed with the fundamental wave component, and newly added as a third-order intermodulation distortion component, thereby causing a further increase in distortion. However, the present embodiment can reduce the distortion of a transmitted signal by preventing the doubled-frequency wave outputted from the amplifier chip 5 from returning thereto with the provision of the harmonic-wave control circuit having the wires 7c2 and the stubs 6b. In particular, the present embodiment is more likely to achieve the effect of suppressing the doubled-frequency wave since the series resonant circuit having the stubs 6b and the wires 7c2 is connected directly to the drain pad DPD of the amplifier chip 5. In general, a problem of increased distortion of an output signal is encountered if an amplifier is operated with a high efficiency. However, the present first embodiment can implement the high-efficiency and low-distortion amplifier AMP1 by providing a structure as described above. It is also possible to reduce leakage power between adjacent channels, which is stringently restricted in the specifications of the W-CDMA system, by the same effect exerted on the intermodulation distortion. Since the wires 7c2 and the stubs 6b are set to constants which bring them into an open state relative to the fundamental wave (i.e., values which increase the impedance with the fundamental wave), the matching circuit for the fundamental wave is barely affected thereby. That is, the constants of the series resonant circuit having the stubs 6b and the wires 7c2 can be set to values which barely affect the fundamental wave so that such a problem of a reduction in the impedance of the amplifier AMP1 with the fundamental wave does not occur. This allows the amplifier AMP1 to be designed similarly to an amplifier circuit as described above with reference to FIGS. 1 to 3 and prevents the situation of difficult design resulting from the provision of the doubled-frequency wave control circuit having the stubs 6b and the wires 7c2. In addition, the stubs 6b are disposed on the empty region without the transmission line 6a of the principal surface of the transmission line substrate 6 and the capacitor insulating film of the capacitor composed of the stubs 6b is composed of the ceramic substrate of the transmission line substrate 6 having a high dielectric constant so that small stubs 6b are sufficient to provide a desired capacitor. As a result, the provision of the stubs 6b does not increase the planar size of the transmission line substrate 6 and does not increase the overall planar size of the amplifier AMP1. There are cases where, if the resonance frequency required of the series resonant circuit is low, an extremely large value is required of the capacitor formed by the stubs 6b so that the formation of the capacitor using the stubs 6b in the transmission line substrate 6 excessively lowers the characteristic impedance and the resultant matching circuit does not function successively as a matching element. In these cases, therefore, it becomes difficult to form the transmission lines 6a and the stubs 6b on the same transmission line substrate 6. However, since the present embodiment uses the frequency of the doubled-frequency wave (frequency double the frequency of the fundamental wave of a transmitted signal) as the resonance frequency, the transmission lines 6a and the stubs 6b can be provided on the same transmission line substrate 6. Moreover, the amplifier AMP1 is mountable on an existing package without involving changes in the size of the transmission line substrate 6 and the number of components is not increased so that the cost for the amplifier AMP1 is not increased. Because of no change in the size of the transmission line substrate 6, it is sufficient only to change bonding in an existing assembly process and there is no need to introduce a new assembly mechanism or a new assembly sequence, which increases the implementability of the amplifier AMP1. In addition, the two stubs 6b are disposed to be symmetrical above and below the narrower portion of the transmission line 6a, as shown in FIG. 8. The two stubs 6b symmetrically disposed facilitate design and improve a characteristic balance. However, the two stubs 6b may also be disposed asymmetrically. It is also possible to dispose only one stub 6b. The planar size (which is a relatively longer size here) of the stub 6b has been adjusted to be sufficiently small (e.g., λ/20) compared with λ/4 where λ is the wavelength of the fundamental wave of a transmitted signal. In the case of using, e.g., a λ/4 line, the planar size of the stub 6b becomes about 3.0 mm when the wavelength λ is 4.28 GHz so that the stub 6b is not accommodated in the empty region of the transmission line substrate 6. If the planar size of the stub 6b is larger than λ/4, the overall size of the amplifier AMP1 may be increased disadvantageously. Although the plan configuration of the stub 6b is, e.g., a rectangle, the plan configuration thereof may be changed variously provided that the stubs 6b can form the capacitor as described above. Each of the stubs 6b has a lengthwise planar dimension L3 of, e.g., about 0.8 mm and a widthwise planar dimension L4 of, e.g., 0.4 mm, which are equivalent to a capacitance of, e.g., about 1 pF. The inductance value of each of the wires 7c2 is, e.g., about 1.4 nH.

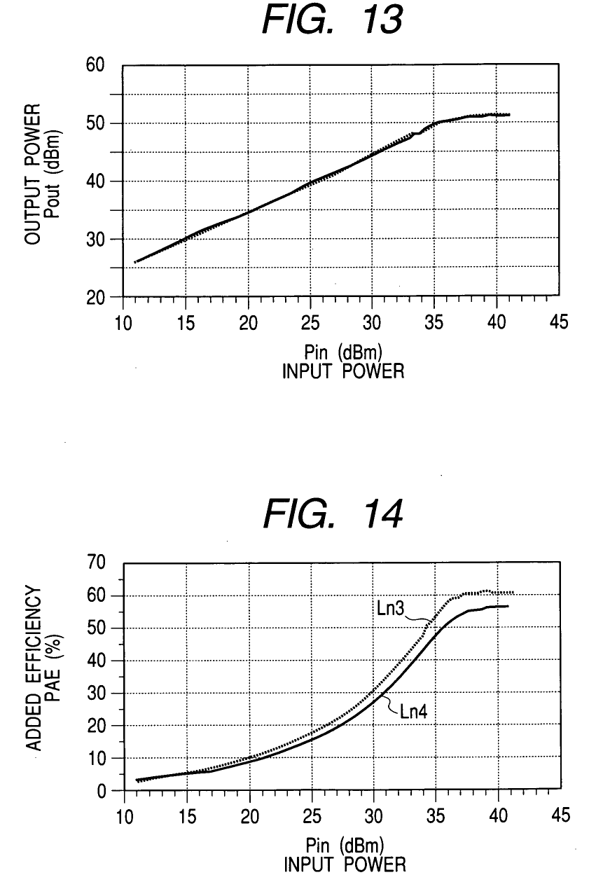

FIG. 11 conceptually shows, for comparison, the respective transmission characteristics of the output internal matching circuits according to the present embodiment (indicated by the solid line Ln1) and the example examined by the inventors (indicated by the broken line Ln2) and shown in FIG. 1 and the like, each relative to frequencies. In the drawing, f0 represents the frequency of the fundamental wave and 2*f0 represents the frequency of the doubled-frequency wave. The foregoing doubled-frequency-wave series resonant circuit according to the present embodiment has been designed to be short-circuited with the doubled-frequency wave such that the fundamental wave is not affected thereby. FIG. 12 shows the frequency characteristic of the doubled-frequency-wave resonant circuit having the stubs 6b and the wires 7c2. The S (21) between the ports Po1 and Po2 is shown in a decibel (dB) representation. Each of the ports Po1 and Po2 is at, e.g., 50 Ω. Although the resonant circuit is resonating at 4.28 GHz, as the frequency of the doubled-frequency wave, it will be understood that 2.14 GHz as the frequency of the fundamental wave is barely affected. FIG. 13 shows, for comparison, the results of simulating the input-output characteristic of the amplifier AMP1 for use at a base station to which the present embodiment has been applied and that of the amplifier according to Example 1 examined by the inventors and described with reference to FIGS. 1 and 3. Calculations have been performed by using the circuit shown in FIG. 3 as Example 1 examined by the inventors and the circuit shown in FIG. 10 as the present embodiment. The same input/output impedance conditions were used (at a load and at a signal source) for the fundamental wave. In FIG. 13, the X-axis represents an input power (Pin) and the Y-axis represents an output power (Pout), each of which is shown in a dBm representation. Since the doubled-frequency-wave resonant circuit barely affects the fundamental wave, the respective input-output characteristics (Pin-Pout) of Example 1 examined by the inventors and the present embodiment have no difference therebetween. FIG. 14 shows, for comparison, the result (Ln3) of simulating the input-efficiency characteristic of the amplifier AMP1 for use at a base station described in the present embodiment and the result (Ln4) of simulating that of the amplifier of Example 1 examined by the inventors and described with reference to FIGS. 1 to 3. In the drawing, the X-axis represents an input power (Pin) and the Y-axis represents a power added efficiency (PAE), which are shown in dBm and % representations, respectively. The efficiency has improved by about 3% at a point about 8 dB backed off from P1 dB. FIG. 15 shows, for comparison, the result (indicated by the solid line) of simulating the distortion characteristic of the amplifier AMP1 for use at a base station described in the present embodiment and the result (indicated by the broken line) of simulating that of the amplifier of Example 1 examined by the inventors and described with reference to FIGS. 1 to 3. The distortions calculated were third-order intermodulation distortions. The input signals are at, e.g., 2.1375 GHz and 2.1425 GHz with a differential frequency Δf=5 MHz. The input/output impedance conditions (at the load side and at the signal source side) are the same as those shown in FIGS. 13 and 14. In the drawing, the X-axis represents the respective output powers (Pout) of the two waves and the Y-axis represents the third-order intermodulation distortions (IMD3) thereof, which are shown in dBm and −dBc representations, respectively. It will be understood that the present embodiment (indicated by the solid line) has improved over Example 1 examined by the inventors (indicated by the broken line) over a range from a low output to a high output. For example, the third-order intermodulation distortion can be reduced by about 1 to 2 dB.

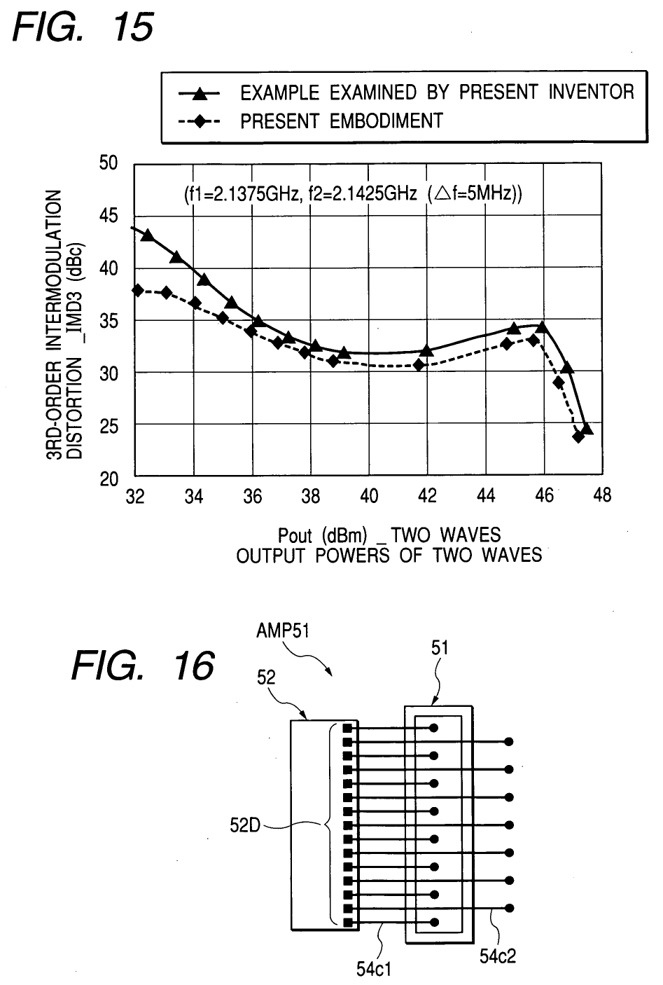

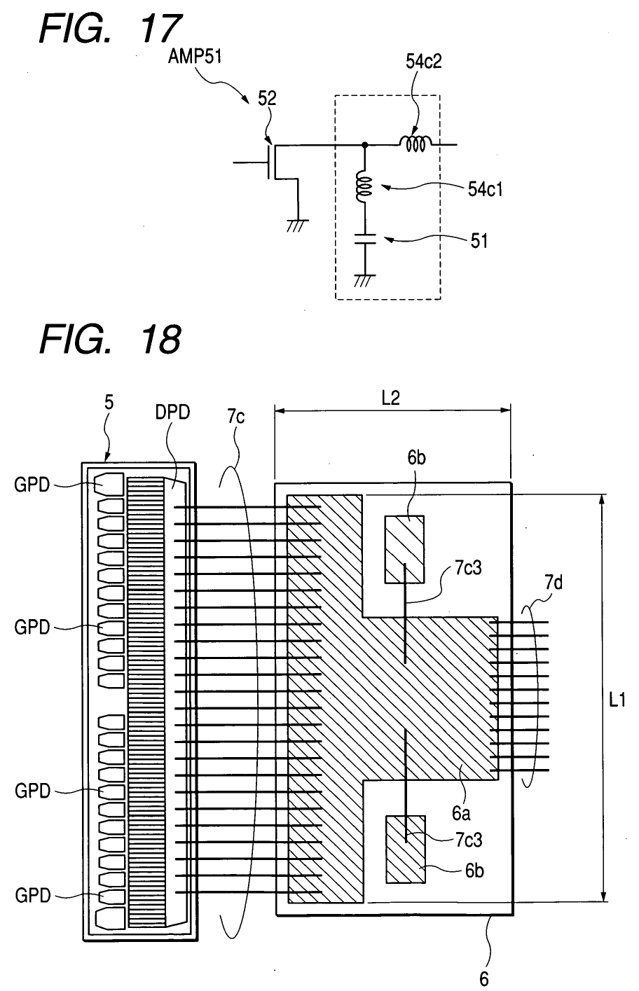

FIG. 16 is a partial plan view of another amplifier AMP51 examined by the present inventors. FIG. 17 is a circuit diagram equivalent to FIG. 16. A reference numeral 52D denotes the drain pad of a MOSFET 52 for amplification. The MOSFET 52 has the desired drain pad 52D connected electrically to a MOS capacitor 51 via wires 54c1 and connected electrically to a lead for outputting via wires 54c2. As a result, a circuit formed by a coil composed of the wires 54c1 and a capacitor composed of the MOS capacitor 51 is connected between the drain of the MOSFET 52 and a ground potential so that the coil of the wire 54c2 is connected between the drain of the MOSFET 52 and a ground potential, while a coil composed of the wires 54c2 is connected between the drain of the MOSFET 52 and the output terminal thereof. In this case, a loss in transmitted signal is large under the influence of the parasitic resistance of the MOS capacitor 51, though cost can be reduced in the absence of a transmission line substrate. The following is the results of a comparison made between the present embodiment and each of Example 1 examined by the inventors and described with reference to FIGS. 1 to 3 and Example 2 examined by the inventors and described with reference to FIGS. 16 and 17. When a comparison was made between, e.g., the respective outputs (powers), the output of the present embodiment was equal to that of Example 1 examined by the inventors and higher than the output of Example 2 examined by the inventors. When a comparison was made between the respective signal transmission efficiencies, the signal transmission efficiency of the present embodiment was the highest, that of Example 1 examined by the inventors was the second highest, and that of Example 2 examined by the inventors was the lowest. When a comparison was made between the respective signal distortions, the signal distortion of the present embodiment was the smallest and Examples 1 and 2 examined by the inventors have substantially the same amount of distortion.

Embodiment 2

A second embodiment of the present invention will describe an example in which one end of a connecting point of a wire composing a series resonant circuit for controlling a doubled-frequency wave is not the drain pad of an amplifier chip but has been changed to a transmission line.

Since the wires 7c2 composing the series resonant circuit for controlling a doubled-frequency wave are connected directly to the drain pad of the amplifier chip 5 in the first embodiment, the number of drain pads (regions) that can be used for the series resonant circuit is limited. The size of each of the stubs 6b used for the series resonant circuit is also limited and the characteristics of the stub 6b are influenced by the dielectric constant of the transmission line substrate 6 so that the inductance value required for each of the wires 7c2 is limited. Consequently, the inductance value of the wire 7c2 has design constraints. Moreover, the effect of the series resonant circuit for controlling a doubled-frequency wave on efficiency is not necessarily exerted optimally by short-circuiting the output end (drain end) of the amplifier chip 5 and the efficiency becomes maximum in a specified phase when only the doubled-frequency wave is controlled.

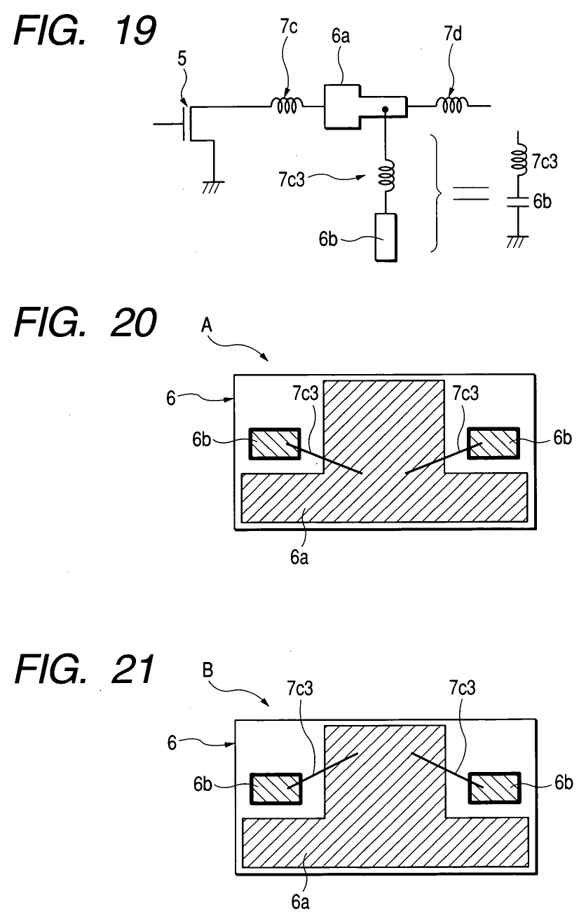

In view of the foregoing, the second embodiment connects the stubs 6b directly to the transmission line 6a via wires (second conductor lines) 7c3 as shown in FIGS. 18 and 19. This obviates the necessity for bonding pads for connecting the doubled-frequency-wave resonant circuit to the amplifier chip 5. In addition, the doubled-frequency-wave resonant circuit can be constructed irrespective of the mounting positions of the amplifier chip 5 and the transmission line substrate 6 (relative positions at which they are disposed). FIG. 19 is a circuit diagram equivalent to FIG. 18. Here, an exemplary case is shown where the connecting points of the wires 7c3 to the stubs 6b and the connecting points of the wires 7c3 to the transmission line 6a are disposed substantially on a virtual straight line which extends vertically in FIG. 18. However, the connecting points of the wires 7c3 onto the transmission line 6a can be determined by selecting optimum points effective to the efficiency and distortion depending on cases. Following is the description thereof.

FIGS. 20 and 21 illustrate the wires 7c3 of types A and B having different connecting points to the transmission line 6a. FIG. 20 shows the case where the connecting points of the wires 7c3 to the transmission line 6a are located to be closer to the wider portion (closer to the amplifier chip 5) of the transmission line 6a than in FIG. 21. FIG. 21 shows the case where connecting points of the wires 7c3 to the transmission line 6a are located to be closer to the narrower portion (closer to the gate lead 2b for outputting) of the transmission line 6a than in FIG. 20. FIGS. 22 to 24 show the results of examinations made by the present inventors on the outputs, efficiencies, and distortions in the case of using the wires 7c3 of the different types A and B. In FIGS. 22 to 24, the sign C indicates the result obtained from Example 1 examined by the inventors and described with reference to FIGS. 1 to 3.

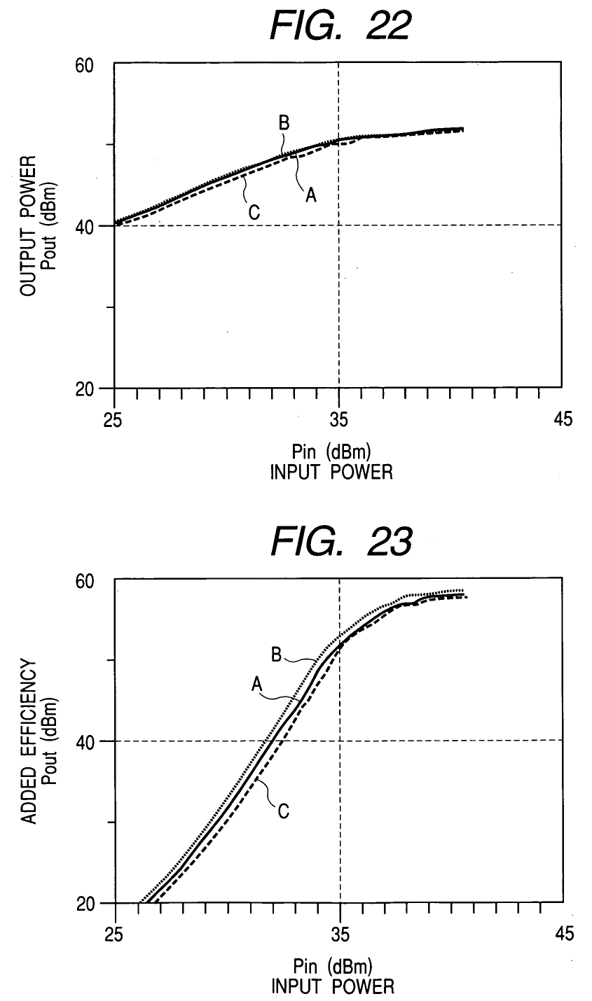

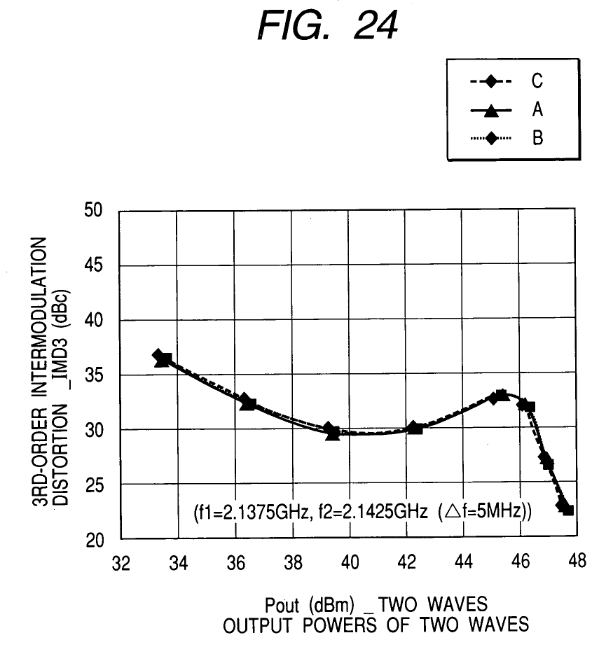

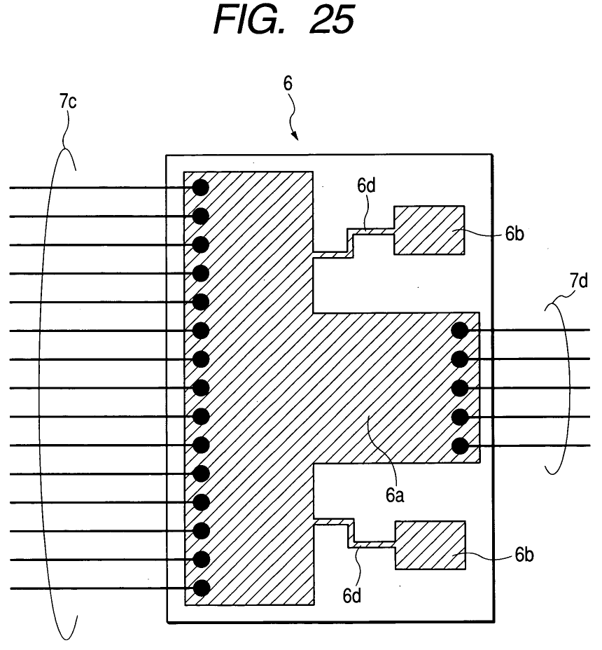

FIG. 22 shows the result of examining the output powers (Pout (dBm)) obtained in the case of using the types A, B, and C, which are substantially the same. FIG. 23 shows the result of examining the power-added efficiencies (PAE (%)) obtained in the case of using the types A, B, and C, of which the power added efficiency obtained with the type B is highest. It will be understood that the power added efficiency obtained with the type A is higher than the power added efficiency obtained with the type C. FIG. 24 shows the result of examining the third-order intermodulation distortions obtained in the case of using the types A, B, and C, which barely show a difference between the types A and B. Thus. the connecting points of the wires 7c3 onto the transmission line 6a which are closer to the amplifier chip 5 do not necessarily provide excellent results. Therefore, the connecting points of the wires 7c3 onto the transmission line 6a are determined individually for each of the amplifiers AMP1 in consideration of the efficiency and distortion. In short, the optimum connecting points of the wires 7c3 onto the transmission line 6a are determined individually for each of the amplifiers AMP1 to respond to requirements placed on the amplifier AMP1. This allows the extraction of optimum characteristics from each of the amplifiers AMP1.

Thus, the present second embodiment achieves the same effects as achieved by the foregoing first embodiment except that the effect of reducing the distortion may be lower than in the first embodiment in some cases. In addition, the second embodiment also achieves the following effects. That is, since the wires 7c3 are connected to the transmission line 6a, constraints placed by the number of the drain pads of the amplifier chip 5 can be eliminated. Moreover, each of the wires 7c3 may have a desired inductance value under substantially no constraint by adjusting the number of the wires 7c3 and the loop configurations thereof. Accordingly, the design flexibility of the amplifier AMP1 can be improved.

Embodiment 3

A third embodiment of the present invention will describe the case where the stubs and the transmission line are connected electrically to each other by using a conductor pattern on the transmission line substrate instead of using the wires 7c3 described in the foregoing second embodiment.

In each of the foregoing first and second embodiments, the inductance value of each of the wires 7c2 and 7c3 forming the series resonant circuit for controlling a doubled-frequency wave should be adjusted depending on the lengths, number, loop heights, and the like of the wires 7c2 and 7c3. Although it is possible to computationally determine the materials and diameters of the wires 7c2 and 7c3 in use and conditions for the lengths, number, and loop heights thereof which satisfy the required inductance value, precise values cannot be determined unless information on the periphery of the wires 7c2 and 7c3 is added and the calculation is not necessarily easy. In addition, bonding which precisely reflects the conditions determined computationally is not easy, either. In an actual assembly process, therefore, adjustment for satisfying the foregoing conditions for the wires 7c2 and 7c3 and causing resonance with a doubled-frequency wave requires labor and time. Briefly, the determination of the conditions for the wires 7c2 and 7c3 in an actual manufacturing line is not necessarily easy. Although there is an approach which computationally determines the conditions by rough estimation, this may cause a new problem of manufacturing variations in the case of mass production. To provide high-quality products with high producibility, therefore, it is not necessarily a good approach to depend on the adjustment of the wires 7c2 and 7c3.

In view of the foregoing, the present third embodiment has replaced the wires 7c2 and 7c3 with a transmission line (conductor pattern) 6d, as shown in FIG. 25, in an approach to solving the foregoing problem associated with manufacturing (mass producibility). In short, the stubs 6b and the transmission line 6a are connected electrically to each other by using the transmission line 6d. The transmission line 6d is a line which is equivalent to the wires 7c2 and 7c3 (i.e., equivalent to a coil) relative to the frequency of a doubled-frequency wave (the frequency double the frequency of the fundamental wave of a transmitted signal). The transmission line 6d is formed on the principal surface of the same transmission line substrate 6 as the transmission line 6a and the stubs 6b. In this case, there is shown an example in which the transmission line 6d is formed into a pattern configuration which is not linear but is bent midway. The pattern configuration of the transmission line 6d may be changed variously provided that the transmission line 6d is equivalent to a coil. For example, the transmission line 6d may also be formed into a meandering pattern. In this case, it is also possible to adjust the inductance value of the transmission line 6d by adjusting the states of meandering (the spacing between adjacent patterns, the length of the adjacent patterns, and the like). The transmission line 6d has been formed by patterning the same metal film as composing the transmission line 6a and the stubs 6b simultaneously with patterning for forming the transmission line 6a and the stubs 6b. Therefore, the transmission line 6d has a higher reproducibility than the wires 7c2 and 7c3. Since the transmission line 6d can be formed thinner than the transmission line 6a and the stubs 6b and can be formed in an empty region without the transmission line 6a and the stubs 6b, the provision of the transmission line 6d does not increase the planar size of the transmission line substrate 6. The connecting point of the transmission line 6d to the transmission line 6a is determined selectively such that a great effect is exerted on efficiency and distortion in the same manner as in the foregoing second embodiment. This optimizes the characteristics of the amplifier AMP1 in the same manner as in the foregoing second embodiment.

Thus, the present third embodiment can achieve not only the same effects as achieved by the foregoing first and second embodiments but also the following effect.

That is, the reproducibility of the inductance value required of the transmission line 6d can be enhanced by providing an electrical connection between each of the stubs 6b and the transmission line 6a by using the pattern of the transmission line 6d so that the reproducibility of the amplifier AMP1 during mass production is improved. In addition, the inductance value computationally allocated to the transmission line 6d can be realized with high reproducibility in an actual product so that the function of the series resonant circuit having the transmission line 6d and the stubs 6b is fully performed and the quality of the amplifier AMP1 is improved. This allows an improved yield rate during the mass production of the amplifier AMP1.

Although the invention achieved by the present inventors has been described specifically with reference to the embodiments thereof, the present invention is not limited thereto. It will be understood that various changes and modifications can be made in the invention without departing from the gist thereof.

Although each of the foregoing embodiments has described the exemplary case where the amplifier element of LDMOS type is formed on the amplifier chip, the present invention is not limited thereto and various changes and modifications can be made. For example, the present invention is also applicable to the case where a HBT (Heterojunction Bipolar Transistor) or a MESFET (Metal Semiconductor Field Effect Transistor) is used.

Although the foregoing description has been given mainly to the case where the invention achieved by the present inventors is applied to the amplifier of an amplifying apparatus for use at a base station which is a field of use as the background of the present invention, the present invention is not limited thereto. The present invention is also applicable to, e.g., the output matching circuit of an RF module for mobile applications.

The following is the brief description of effects achievable by the representative aspects of the invention disclosed in the present application.

That is, the performance of a semiconductor device for amplification used at a base station can be improved by providing an amplifier element and a transmission line substrate in a package composing the semiconductor device for amplification which is used at a base station, connecting stubs formed on the empty region of the transmission line substrate to the output of the amplifier element by using conductor lines, and connecting a resonant circuit which resonates at a frequency double the fundamental frequency of an output signal from the amplifier element.

What is claimed is:

1. A semiconductor device comprising:
a semiconductor active element including an input portion and an output portion;
a transmission line substrate;
a transmission line on said transmission line substrate, said transmission line being connected electrically to said output portion of said semiconductor active element via a first conductor line; and
a stub over said transmission line substrate, said stub being connected electrically to said output portion of said semiconductor active element via a second conductor line,
wherein said transmission line is formed to have a width larger at a portion thereof closer to said semiconductor active element than at a portion thereof more distant from said semiconductor active element and
wherein said second conductor line and said stub form a circuit resonating at a frequency double a fundamental frequency of an output signal from said semiconductor active element.

2. A semiconductor device according to claim 1, wherein an output impedance of said semiconductor active element is 2 Ω or less.

3. A semiconductor device according to claim 1, wherein said transmission line has a protruding configuration which is larger in width at a portion thereof closer to an output of said semiconductor active element.

4. A semiconductor device according to claim 3, which is used in an amplifying apparatus for use at a mobile phone base station.

5. A semiconductor device according to claim 3, wherein said stub is formed in an empty region without said transmission line of the surface of said transmission line substrate which is formed with said transmission line.

6. A semiconductor device according to claim 5 wherein a conductor film is provided over the surface of said transmission line substrate which is opposite to the surface thereof formed with said transmission line and said conductor film is set to a reference potential.

7. A semiconductor device according to claim 6, wherein said transmission line substrate includes a ceramic substrate as a base substrate.

8. A semiconductor device according to claim 6, wherein said transmission line substrate has a base substrate comprised of a dielectric and a conductor film formed over said base substrate and said dielectric has a specific dielectric constant higher than 20.

9. A semiconductor device according to claim 5, wherein said semiconductor active element includes a field effect transistor including a source, agate, and a drain and the output of said semiconductor active element is the drain of said field effect transistor.

10. A semiconductor device according to claim 9, wherein said field effect transistor is an LDMOS.

11. A semiconductor device according to claim 9, wherein a total gate width of said field effect transistor is 20 mm or more.

12. A semiconductor device according to claim 5, wherein said stub has a rectangular configuration and a longer edge of said stub has a length smaller than 1/4 of the fundamental frequency of said output signal.

13. A semiconductor device according to claim 5, wherein said second conductor line is a bonding wire.

14. A semiconductor device according to claim 5, wherein said second conductor line is a wiring pattern formed over said transmission line substrate.

15. A semiconductor device comprising:
a semiconductor active element including an input portion and an output portion;
a transmission line substrate;
a transmission line over said transmission line substrate, said transmission line being connected electrically to said output portion of said semiconductor active element via a first conductor line; and
a stub over said transmission line substrate, said stub being connected electrically to said output portion of said semiconductor active element via a second conductor line, wherein said transmission line has a protruding configuration having a width larger at a portion thereof closer to said semiconductor active element than at a portion thereof more distant from said semiconductor active element and wherein said second conductor line and said stub form a circuit resonating at a frequency double a fundamental frequency of an output signal from said semiconductor active element.

16. A semiconductor device comprising, in a single package:
(a) a lead for inputting;
(b) a capacitor element connected electrically to said lead for inputting via a conductor line;
(c) an amplifier element connected electrically to said capacitor element via a conductor line;
(d) a transmission line substrate including a transmission line connected electrically to an output of said amplifier element via a first conductor line and a stub connected electrically to the output of said amplifier element via a second conductor line comprised of a bonding wire, said transmission line having a protruding configuration which is larger in width at a portion closer to said amplifier element than at a portion thereof more distant from said amplifier element; and
(e) a lead for outputting connected electrically to said transmission line via a conductor line,
wherein said stub is formed in an empty region without said transmission line of the surface of said transmission line substrate which is formed with said transmission line, wherein
said transmission line substrate has a base substrate comprised of a ceramic having a specific dielectric constant higher than 20 and a conductor film formed over said base substrate and a reference potential is applied to the conductor film provided over the surface of said transmission line substrate which is opposite to the surface thereof formed with said transmission line, and
wherein said second conductor line and the stub form a circuit resonating at a frequency double a fundamental frequency of an output signal from said amplifier element.

17. A semiconductor device according to claim 16, which is used in an amplifying apparatus for use at a mobile phone base station.

18. A semiconductor device comprising, in a single package:
(a) a semiconductor active element;
(b) a transmission line substrate;
(c) a transmission line formed over said transmission line substrate and including first and second portions;
(d) a first conductor line connected to an output portion of said semiconductor active element and connected to said first portion of said transmission line to provide an electrical connection between said semiconductor active element and the transmission line;
(e) a stub formed over said transmission line substrate; and
(f) a second conductor line connected to the output portion of said semiconductor active element and connected to said stub to provide an electrical connection between said semiconductor active element and the stub,
wherein said second conductor line and the stub form a circuit resonating at a frequency double a fundamental frequency of an output signal from said semiconductor active element.

19. A semiconductor device according to claim 18, which is used in an amplifying apparatus for use at a mobile phone base station.

20. A semiconductor device according to claim 18, wherein the first portion of said transmission line is lower in impedance than the second portion of said transmission line.

21. A semiconductor device according to claim 18, wherein said semiconductor active element is a field effect transistor, an output of said semiconductor active element is a drain of the field effect transistor, and a total gate width of said field effect transistor is 20 mm or more.

22. A semiconductor device according to claim 18, wherein said transmission line is formed into a protruding plan configuration in which said first portion relatively close to an output of said semiconductor active element is larger in width than said second portion relatively distant from the output of said semiconductor active element.

23. A semiconductor device comprising:
a semiconductor active element including an input portion and an output portion;
a transmission line substrate;
a transmission line over said transmission line substrate, said transmission line being connected electrically to said output portion of said semiconductor active element via a first conductor line; and
a conductor piece over said transmission line substrate, said conductor piece being connected electrically to said output portion of said semiconductor active element via a second conductor line,
wherein said transmission line has a protruding configuration which is larger in width at a portion thereof closer to said semiconductor active element than at a portion thereof more distant from said semiconductor active element and said conductor piece is formed in an empty region without said transmission line of the surface of said transmission line substrate which is formed with said transmission line.
